(19) United States
(12) Patent Application Publication
(10) Pub. No.: US 2025/0095729 A1
(43) Pub. Date: Mar. 20, 2025

(54) STORAGE DEVICE

(71) Applicant: Kioxia Corporation, Tokyo (JP)

(72) Inventor: Kazuya MATSUZAWA, Kamakura Kanagawa (JP)

(73) Assignee: Kioxia Corporation, Tokyo (JP)

(21) Appl. No.: 18/816,540

(22) Filed: Aug. 27, 2024

(30) Foreign Application Priority Data
Sep. 20, 2023 (JP) 2023-152169

(51) Int. Cl. G11C 13/00

(52) U.S. Cl. CPC G11C 13/004; G11C 13/0007; G11C 13/0061; G11C 2013/0054

(57) ABSTRACT

A storage device includes: a first wiring; a second wiring; a memory cell provided between the first wiring and the second wiring, the memory cell including a resistance change storage element configured in a first resistance state or a second resistance state, and a selector connected to the resistance change storage element and configured to shift from off-state to on-state when voltage higher than a first threshold voltage is applied; a switching element configured to input a first signal from the second wiring and output a second signal to a third wiring; a voltage application circuit configured to apply a first voltage to the first wiring at a first time point; and a determination circuit configured to determine the resistance state of the resistance change storage element based on the second signal output to the third wiring at a second time point after the first time point.

### CROSS-REFERENCE TO RELATED APPLICATION(S)

This application is based upon and claims the benefit of priority from Japanese Patent Application No. 2023-152169, filed Sep. 20, 2023, the entire contents of which are incorporated herein by reference.

### FIELD

Embodiments described herein relate generally to a storage device.

### BACKGROUND

Provided is a storage device in which a plurality of memory cells each including a resistance change storage element such as a magnetoresistive effect element, and a selector for selecting the resistance change storage element is integrated on a semiconductor substrate.

### DESCRIPTION OF THE DRAWINGS

FIG. 1 is a block diagram showing an entire configuration of a storage device according to a first embodiment.

FIG. 2 is a perspective view schematically showing a configuration of a memory cell array unit of the storage device according to the first embodiment.

FIG. 3 is a cross-sectional view schematically showing a basic configuration of a magnetoresistive effect element of the storage device according to the first embodiment.

FIG. 4 is an electric circuit diagram showing a configuration of a circuit including a switching element of the storage device according to the first embodiment and the like.

FIG. 5 is a diagram showing a voltage application circuit of the storage device according to the first embodiment.

FIG. 6 is a diagram showing a determination circuit of the storage device according to the first embodiment.

FIG. 7 is a timing chart schematically showing a read operation of the storage device according to the first embodiment.

FIG. 8 is a diagram showing a specific example of voltage change of a bit line and an output wiring in the storage device according to the first embodiment.

FIG. 9 is an electric circuit diagram showing a configuration of a circuit including a switching element of a storage device according to a second embodiment and the like.

FIG. 10 is a timing chart schematically showing a read operation of the storage device according to the second embodiment.

FIG. 11 is a diagram showing a specific example of voltage change of a bit line and an output wiring in the storage device according to the second embodiment.

FIG. 12 is an electric circuit diagram showing a configuration of a circuit including a switching element of a storage device according to a third embodiment and the like.

FIG. 13 is an electric circuit diagram showing a configuration of a circuit including a switching element of a storage device according to a fourth embodiment and the like.

### DETAILED DESCRIPTION

Embodiments provide a storage device capable of performing an appropriate read operation.

In general, according to one embodiment, a storage device includes: a first wiring extending in a first direction; a second wiring extending in a second direction intersecting the first direction; a memory cell provided between the first wiring and the second wiring, the memory cell including a resistance change storage element configured in a first resistance state or a second resistance state, and a selector connected in series to the resistance change storage element and configured to shift from off-state to on-state when voltage higher than a first threshold voltage is applied, the memory cell configured to store data based on a resistance state of the resistance change storage element; a switching element configured to input a first signal from the second wiring and output a second signal to third wiring different from the first wiring and the second wiring; a voltage application circuit configured to apply a first voltage to the first wiring at a first time point such that a voltage higher than the first threshold voltage is applied to the selector; and a determination circuit configured to determine the resistance state of the resistance change storage element based on the second signal output to the third wiring at a second time point after the first time point.

Hereinafter, embodiments will be described with reference to the drawings.

### First Embodiment

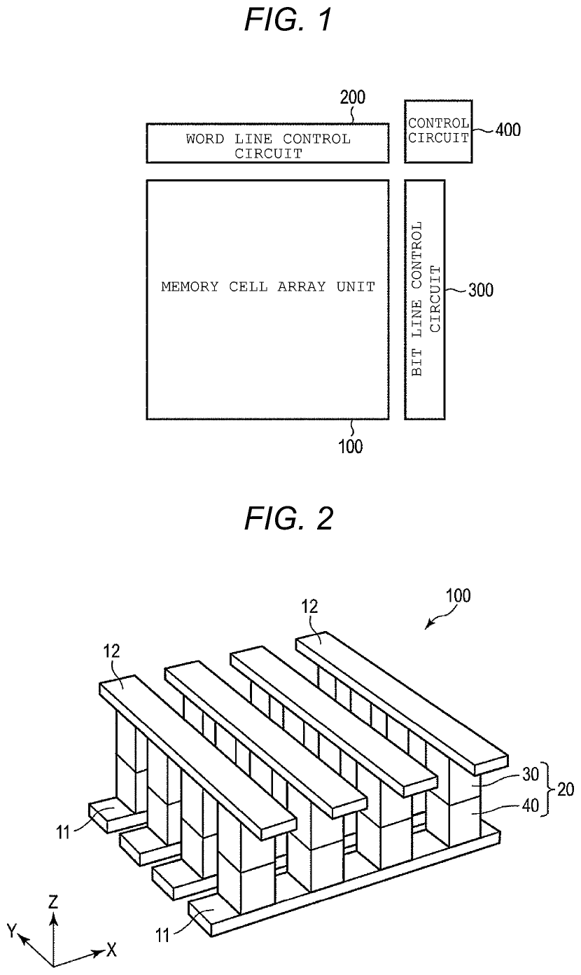

FIG. 1 is a block diagram showing an entire configuration of a storage device according to a first embodiment.

The storage device according to the present embodiment includes a memory cell array unit 100, a word line control circuit 200, a bit line control circuit 300, and a control circuit 400.

FIG. 2 is a perspective view schematically showing a configuration of the memory cell array unit 100.

The memory cell array unit 100 includes a plurality of word lines (first wirings) 11 each extending in an X direction, a plurality of bit lines (second wirings) 12 each extending in a Y direction, and a plurality of memory cells 20 each provided (connected) between corresponding word lines 11 and corresponding bit lines 12.

Each of the memory cells 20 includes a magnetoresistive effect element 30 that is a resistance change storage element and a selector 40 connected in series to the magnetoresistive effect element 30. The magnetoresistive effect element 30 and the selector 40 are stacked in a Z direction.

The X direction, the Y direction, and the Z direction described above are directions intersecting one another. In the present embodiment, the X direction, the Y direction, and the Z direction are orthogonal to one another.

In the example shown in FIG. 2, the word lines 11 are provided on the lower layer side and the bit lines 12 are provided on the upper layer side; alternatively, the word lines 11 may be provided on the upper layer side and the bit lines 12 may be provided on the lower layer side. In addition, in the example shown in FIG. 2, the magnetoresistive effect element 30 is provided on the upper layer side and the selector 40 is provided on the lower layer side; alternatively, the magnetoresistive effect element 30 may be provided on the lower layer side and the selector 40 may be provided on the upper layer side.

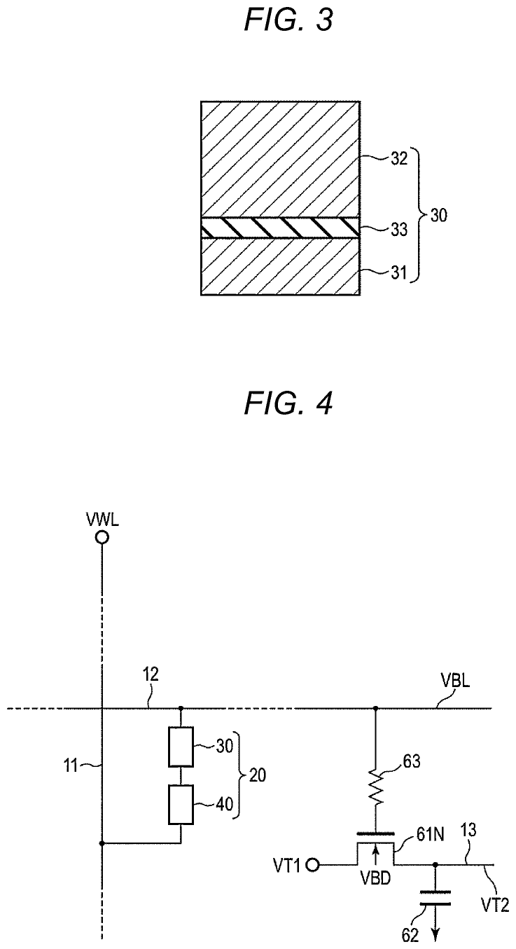

FIG. 3 is a cross-sectional view schematically showing a basic configuration of the magnetoresistive effect element 30.

The magnetoresistive effect element 30 is a magnetic tunnel junction (MTJ) element and includes a storage layer 31, a reference layer 32, and a tunnel barrier layer 33. The storage layer 31 is a ferromagnetic layer having a variable magnetization direction. The reference layer 32 is ferromagnetic layer having a fixed magnetization direction. The tunnel barrier layer 33 is a non-magnetic layer and an insulating layer provided between the storage layer 31 and the reference layer 32. In the example shown in FIG. 3, the storage layer 31 is provided on the lower layer side of the reference layer 32; alternatively, the storage layer 31 may be provided on the upper layer side of the reference layer 32.

The magnetoresistive effect element 30 can be in a low resistance state and a high resistance state having a higher resistance than the low resistance state. When the magnetization direction of the storage layer 31 is parallel to the magnetization direction of the reference layer 32, the magnetoresistive effect element 30 is in a low resistance state. When the magnetization direction of the storage layer 31 is antiparallel to the magnetization direction of the reference layer 32, the magnetoresistive effect element 30 is in a high resistance state. As a result, the magnetoresistive effect element 30 can store binary data in accordance with the resistance state. That is, the memory cell 20 can store the data based on the resistance state set in the magnetoresistive effect element 30.

The selector 40 is a bidirectional 2-terminal switching element, and has a characteristic of shifting from off-state to on-state when the voltage higher than threshold voltage is applied between two terminals (between a first terminal and a second terminal). For example, an element having a configuration in which an insulation material is interposed between two electrodes (between two terminals) may be used for the selector 40. For example, silicon oxide containing arsenic and the like may be used for the insulation material.

When voltage is applied between the selected word line 11 and the selected bit line 12 that are connected to the selected memory cell 20 (memory cell 20 on which writing or reading is performed) and the voltage higher than the threshold voltage is applied to the selector 40, the selector 40 provided in the selected memory cell 20 enters on-state and the current flows in the magnetoresistive effect element 30 provided in the selected memory cell 20. As a result, it is possible to perform writing or reading to the magnetoresistive effect element 30 provided in the selected memory cell 20.

In the following description, unless otherwise indicated, the selected memory cell 20, the magnetoresistive effect element 30 provided in the selected memory cell 20, the selector 40 provided in the selected memory cell 20, the selected word line 11, and the selected bit line 12 may be simply referred to as a memory cell 20, a magnetoresistive effect element 30, a selector 40, a word line 11, and a bit line 12.

The word line 11 is connected to the word line control circuit 200, and the word line 11 is controlled by the word line control circuit 200. The bit line 12 is connected to the bit line control circuit 300, and the bit line 12 is controlled by the bit line control circuit 300. It is possible to perform writing or reading to the memory cell 20 by supplying a control signal (drive signal) to the word line 11 and the bit line 12 from the word line control circuit 200 and the bit line control circuit 300, respectively.

The control circuit 400 control the word line control circuit 200 and the bit line control circuit 300.

In addition, as shown in FIGS. 4, 5, and 6, the storage device according to the present embodiment includes a switching element (in the example of FIG. 4, N-type MOS transistor 61N), a voltage application circuit 70, a determination circuit 80 and the like.

The MOS transistor 61N is a transistor that inputs a voltage signal (first signal) VBL from the bit line 12 and outputs a voltage signal (second signal) VT2 to output wiring (third wiring) 13 different from the word line 11 and the bit line 12, and is provided for each bit line 12.

Specifically, the MOS transistor 61N includes a gate terminal, the first terminal corresponding to one terminal of a source terminal and a drain terminal, and the second terminal corresponding to the other terminal of the source terminal and the drain terminal. The voltage signal VBL is input from the bit line 12 to the gate terminal, a voltage signal VT1 is input to the first terminal, and the voltage signal VT2 is output from the second terminal to the output wiring 13. In addition, body voltage VBD is applied to the body of the MOS transistor 61N.

A capacitor 62 is provided in the output wiring 13, and resistance 63 is provided between the gate terminal of the MOS transistor N and the bit line 12. The capacitor 62 accompanies the output wiring 13, and a capacitor element may be used as the capacitor 62. Alternatively, a parasitic capacitance component such as the output wiring 13 may be used as the capacitor 62. Similarly, a resistance element may be used as the resistance 63. Alternatively, a parasitic resistance component such as wiring may be used as the resistance 63.

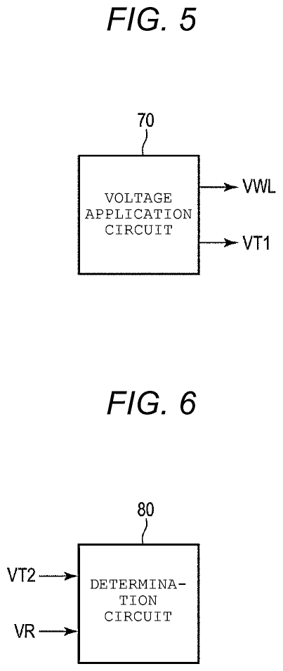

The voltage application circuit 70 shown in FIG. 5 mainly applies the voltage signal to the word line 11 and the first terminal of the MOS transistor 61N. That is, a voltage signal VWL is applied to the word line 11, and the voltage signal VT1 is applied to the first terminal of the MOS transistor 61N. At least a part of the voltage application circuit 70 is provided in the word line control circuit 200 shown in FIG. 1.

The determination circuit 80 shown in FIG. 6 determines a resistance state (low resistance state, high resistance state) set in the magnetoresistive effect element 30. Specifically, the voltage signal VT2 of the output wiring 13 and reference voltage VR are input to the determination circuit 80, and the resistance state set in the magnetoresistive effect element 30 is determined by comparing the voltage (potential) VT2 with the reference voltage (reference potential) VR. At least a part of the determination circuit 80 is provided in the bit line control circuit 300 shown in FIG. 1.

Next, operations of the storage device according to the present embodiment will be described.

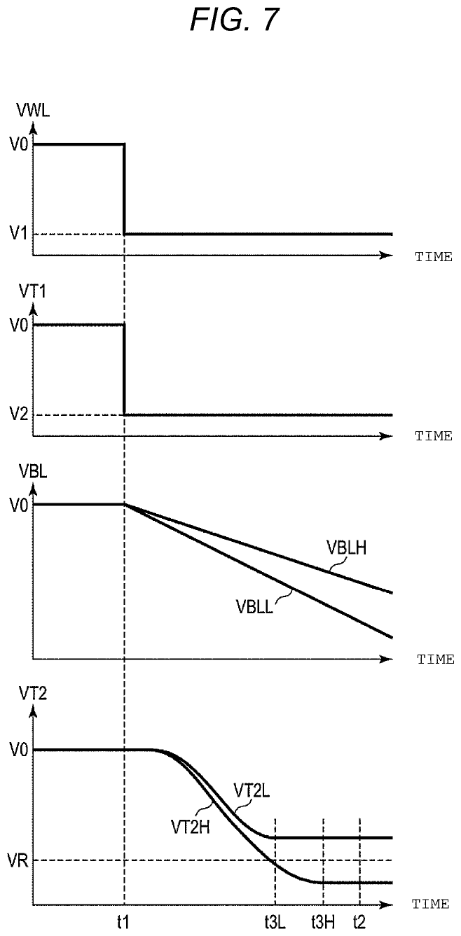

FIG. 7 is a timing chart schematically showing a read operation of the storage device according to the present embodiment. Specifically, FIG. 7 is a diagram showing the voltage (potential) VWL of the word line 11, the voltage (potential) VT1 of the first terminal of the MOS transistor 61N, the voltage (potential) VBL of the bit line 12, and the voltage (potential) VT2 of the second terminal of the MOS transistor 61N. For convenience, in FIG. 7, the scale of the vertical axis is different among the voltage VWL, the voltage VT1, the voltage VBL, and the voltage VT2.

In an initial state (a state at a time point before a time point t1), the voltage VWL, the voltage VT1, the voltage VBL, and the voltage VT2 are the same voltage V0, and the bit line 12 and the output wiring 13 are maintained to be in a floating state. For example, the voltage V0 is 4V, and the body voltage (body potential) VBD of the MOS transistor 61N is 2V.

At the time point t1 (first time point), by the voltage application circuit 70, the voltage VWL of the word line 11 changes from V0 to V1, and the voltage VT1 of the first terminal of the MOS transistor 61N changes from V0 to V2. The difference (absolute value) between the voltage V0 and voltage V1 is greater than the difference (absolute value) between the voltage V0 and voltage V2. For example, the voltage V1 is 0V, and the voltage V2 is 2V. The body voltage VBD is maintained to be 2V.

As described above, the time point when the voltage VT1 changes from V0 to V2 is desirably synchronized (consistent) with the time point when the voltage VWL changes from V0 to V1; however, if the time point when the voltage VT1 changes is sufficiently earlier than a time point t2, a time point t3L and a time point t3H to be described later, the time point when the voltage VT1 changes may be slightly different from the time point when the voltage VWL changes.

When the voltage VWL of the word line 11 is changed into V1 (first voltage) at the time point t1, the voltage (V0-V1) is applied to the memory cell 20 connected between the word line 11 and the bit line 12, and the selector 40 shifts from off-state to on-state. In other words, a value of the voltage V0 and a value of the voltage V1 are set such that the voltage higher than the threshold voltage of the selector 40 is applied to the selector 40 at the time point t1.

When the selector 40 enters on-state at the time point t1 and the current flows in the memory cell 20, the voltage (potential) VBL of the bit line 12 gradually decreases. That is, since the bit line 12 is maintained to be in a floating state, the charge stored by the bit line 12 is discharged and the voltage (potential) VBL of the bit line 12 gradually decreases after the time point t1.

When the selector 40 is in an on-state, the resistance (series resistance of the magnetoresistive effect element 30 and the selector 40) of the memory cell 20 heavily depends on the resistance value of the magnetoresistive effect element 30. That is, the decreasing rate of voltage (potential) VBLL of the bit line 12 when the magnetoresistive effect element 30 is in a low resistance state is larger than the decreasing rate of voltage (potential) VBLH of the bit line 12 when the magnetoresistive effect element 30 is in a high resistance state.

In addition, when the voltage VT1 of the first terminal of the MOS transistor 61N changes from V0 to V2 at the time point t1, the MOS transistor 61N enters on-state and additionally, the potential difference occurs between the first terminal and the second terminal of the MOS transistor 61N. Therefore, the discharge current based on the charge stored by the capacitor 62 flows in the MOS transistor 61N. As a result, the voltage (potential) VT2 of the output wiring 13 gradually decreases.

The voltage VBL of the bit line 12 is applied to the gate terminal of the MOS transistor 61N via the resistance 63. Therefore, the discharge characteristic of the capacitor 62 depends on the voltage (potential) VBL of the bit line 12, and the voltage (potential) VT2 of the output wiring 13 depends on the voltage (potential) VBL of the bit line 12. As shown in FIG. 7, when the characteristic of the voltage (potential) of the bit line 12 is the VBLL, the change of the voltage (potential) of the output wiring 13 is VT2L, and when the characteristic of the voltage (potential) of the bit line 12 is the VBLH, the change of the voltage (potential) of the output wiring 13 is VT2H.

As seen from FIG. 7, the decreasing rate of the voltage (potential) VBLL of the bit line 12 when the magnetoresistive effect element 30 is in a low resistance state is larger than the decreasing rate of the voltage (potential) VBLH of the bit line 12 when the magnetoresistive effect element 30 is in a high resistance state. Therefore, the time point t3L (third time point) when the MOS transistor 61N enters off-state when the magnetoresistive effect element 30 is in a low resistance state is a time point before the time point t3H (third time point) when the MOS transistor 61N enters off-state when the magnetoresistive effect element 30 is in a high resistance state.

When the MOS transistor 61N enters off-state, the discharge of the capacitor 62 is stopped, and the voltage (potential) VT2 of the output wiring 13 becomes a fixed value. As described above, the time point t3L is a time point before the time point t3H. Therefore, after the MOS transistor 61N enters off-state, a great difference occurs between the voltage (potential) VT2L and the voltage (potential) VT2H of the output wiring 13.

Thus, at the time point t2 (second time point) after the time point t3L and the time point t3H, the resistance state set in the magnetoresistive effect element 30 is determined by the determination circuit 80. That is, based on the voltage (potential) VT2 of the output signal output to the output wiring 13 at the time point t2, the resistance state set in the magnetoresistive effect element 30 is determined. More specifically, the resistance state set in the magnetoresistive effect element 30 is determined by comparing the voltage (potential) VT2 of the output wiring 13 at the time point t2 with the reference voltage (reference potential) VR.

When the voltage (potential) VT2 is higher than the reference voltage (reference potential) VR, it is determined that the low resistance state is set in the magnetoresistive effect element 30. When the voltage (potential) VT2 is lower than the reference voltage (reference potential) VR, it is determined that the high resistance state is set in the magnetoresistive effect element 30.

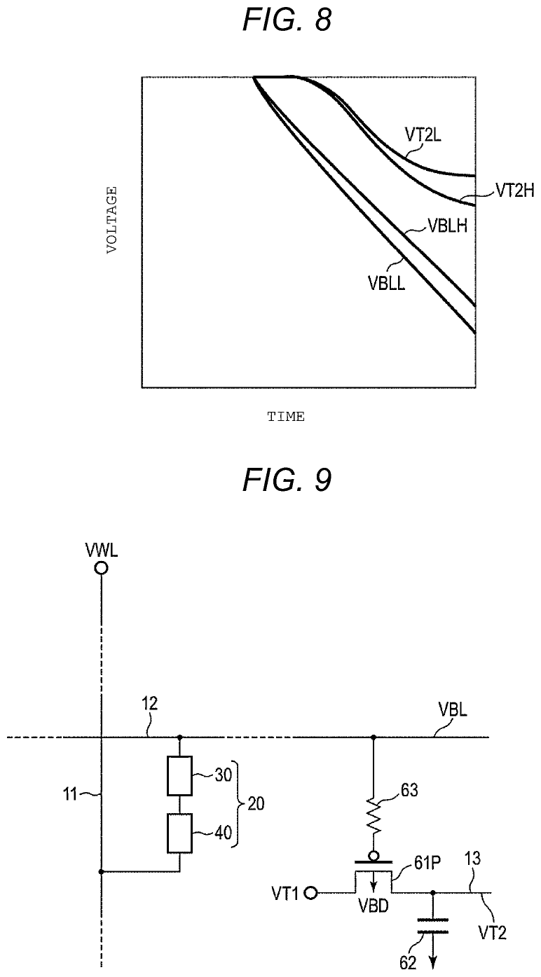

FIG. 8 is a diagram showing a specific example of the change of the voltage (potential) VBLL and VBLH of the bit line 12 described above and the change of the voltage (potential) VT2L and VT2H of the output wiring 13 described above. As shown in FIG. 8, each of the VBLL, the VBLH, the VT2L, and the VT2H represents the characteristic as described with reference to FIG. 7.

As described above, in the present embodiment, the voltage signal VBL from the bit line 12 is input to the switching element (MOS transistor 61N), and based on the voltage signal VT2 output from the switching element (MOS transistor 61N) to the output wiring 13, the resistance state set in the magnetoresistive effect element 30 is determined. As a result, it is possible to perform an appropriate read operation.

If the resistance state of the magnetoresistive effect element 30 is determined by using the voltage signal VBL of the bit line 12, the voltage signal VBL simply decreases according to the elapsed time, and it is difficult to perform a determination operation correctly at an appropriate timing.

In the present embodiment, the decrease in the voltage signal VBL of the bit line 12 allows the MOS transistor 61N to shift from on-state to off-state. Since the decreasing rate of the voltage signal VBL of the bit line 12 depends on the resistance state of the magnetoresistive effect element 30, a time point when the MOS transistor 61N shifts from on-state to off-state also depends on the resistance state of the magnetoresistive effect element 30. Therefore, it is possible to generate a great difference in the voltage (potential) VT2 of the output wiring 13 when the MOS transistor 61N enters off-state between the case where the magnetoresistive effect element 30 is in a low resistance state and the case where the magnetoresistive effect element 30 is in a high resistance state. As a result, it is possible to determine the resistance state of the magnetoresistive effect element 30 in an appropriate manner. In addition, after the MOS transistor 61N enters off-state, a value of the voltage (potential) VT2 of the output wiring 13 hardly changes. As a result, in the present embodiment, it is possible to obtain a sufficient margin in terms of time and perform an appropriate read operation.

### Second Embodiment

Next, a storage device according to a second embodiment will be described. Basic matters are the same as those in the first embodiment, and description of the matters described in the first embodiment is omitted.

FIG. 9 is an electric circuit diagram showing a configuration of a circuit including a switching element of the storage device according to the present embodiment and the like.

In the present embodiment, a P-type MOS transistor 61P is used as a switching element. The other basic configurations are similar to those of the first embodiment.

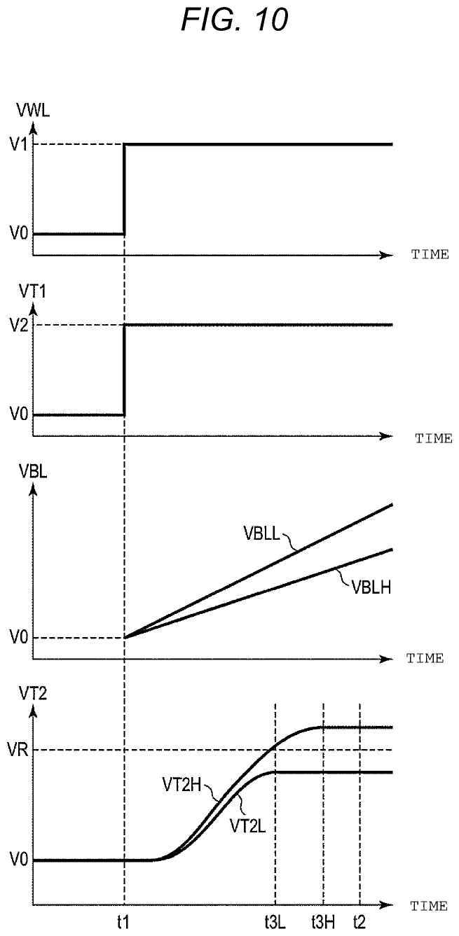

FIG. 10 is a timing chart schematically showing a read operation of the storage device according to the present embodiment. Specifically, FIG. 10 is a diagram showing the voltage (potential) VWL of the word line 11, the voltage (potential) VT1 of the first terminal of the MOS transistor 61P, the voltage (potential) VBL of the bit line 12, and the voltage (potential) VT2 of the second terminal of the MOS transistor 61P. Similarly to that in FIG. 7 of the first embodiment, the scale of the vertical axis is different among the voltage VWL, the voltage VT1, the voltage VBL, and the voltage VT2.

The basic read operation of the present embodiment is similar to the read operation of the first embodiment described with reference to FIG. 7, and the time points t1, t2, t3L, and t3H are also similar to the time points t1, t2, t3L, and t3H of the first embodiment. However, in the present embodiment, since the P-type MOS transistor 61P is used as the switching element, the direction in which the voltage changes is different from that of the first embodiment.

In the initial state (the state at a time point before the time point t1), similarly to the first embodiment, the voltage VWL, the voltage VT1, the voltage VBL, and the voltage VT2 are the same V0, and the bit line 12 and the output wiring 13 are maintained to be in a floating state. In the present embodiment, for example, the voltage V0 is 0V, and the body voltage (body potential) VBD of the MOS transistor 61P is 2V.

At the time point t1, similarly to the first embodiment, the voltage VWL of the word line 11 changes from V0 to V1 and the voltage VT1 of the first terminal of the MOS transistor 61P changes from V0 to V2. Also in the present embodiment, the difference (absolute value) between the voltage V0 and the voltage V1 is greater than the difference (absolute value) between the voltage V0 and the voltage V2. For example, the voltage V1 is 4V, and the voltage V2 is 2V. The body voltage VBD is maintained to be 2V.

Also in the present embodiment, similarly to the first embodiment, at the time point t1, the selector 40 shifts from off-state to on-state, and the current flows in the memory cell 20. However, in the present embodiment, the voltage (potential) VBL of the bit line 12 gradually increases after the time point t1. In the present embodiment, the increasing rate of the voltage (potential) VBLL of the bit line 12 when the magnetoresistive effect element 30 is in a low resistance state is larger than the increasing rate of the voltage (potential) VBLH of the bit line 12 when the magnetoresistive effect element 30 is in a high resistance state.

In the present embodiment, in accordance with the increase of the voltage (potential) VBL of the bit line 12, the voltage (potential) VT2 of the output wiring 13 also increases. Specifically, when the change of the voltage (potential) of the bit line 12 is the VBLL, the change of the voltage (potential) of the output wiring 13 is the VT2L, and when the change of the voltage (potential) of the bit line 12 is the VBLH, the change of the voltage (potential) of the output wiring 13 is the VT2H.

Also in the present embodiment, similarly to the first embodiment, when the magnetoresistive effect element 30 is in a low resistance state, the time point when the MOS transistor 61P sifts from on-state to off-state is the time point t3L, and when the magnetoresistive effect element 30 is in a high resistance state, the time point when the MOS transistor 61P sifts from on-state to off-state is the time point t3H.

Thus, also in the present embodiment, similarly to the first embodiment, at the time point t2 after the time point t3L and the time point t3H, the resistance state set in the magnetoresistive effect element 30 is determined. That is, the resistance state set in the magnetoresistive effect element 30 is determined by comparing the voltage (potential) VT2 of the output wiring 13 at the time point t2 with the reference voltage (reference potential) VR. In the present embodiment, when the voltage (potential) VT2 is lower than the reference voltage (reference potential) VR, it is determined that the low resistance state is set in the magnetoresistive effect element 30, and when the voltage (potential) VT2 is higher than the reference voltage (reference potential) VR, it is determined that the high resistance state is set in the magnetoresistive effect element 30.

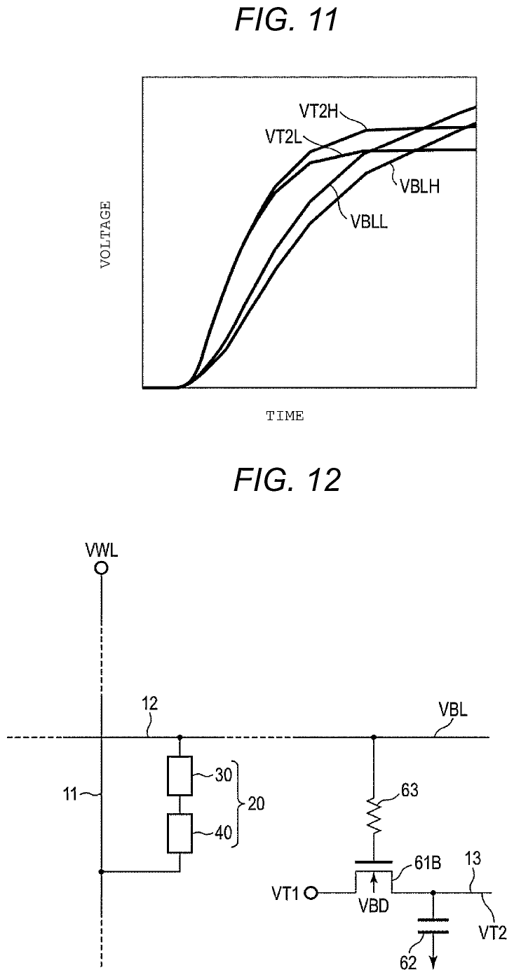

FIG. 11 is a diagram showing a specific example of the change of the voltage (potential) VBLL and VBLH of the bit line 12 described above and the change of the voltage (potential) VT2L and VT2H of the output wiring 13 described above. As shown in FIG. 11, each of the VBLL, the VBLH, the VT2L, and the VT2H represents the characteristic as described with reference to FIG. 10.

The present embodiment is also similar to the first embodiment in basic configurations and basic operations and can obtain similar effects to those of the first embodiment.

### Third Embodiment

Next, a storage device according to a third embodiment will be described. Basic matters are similar to those of the first and the second embodiments, and description of the matters described in the first and the second embodiments is omitted.

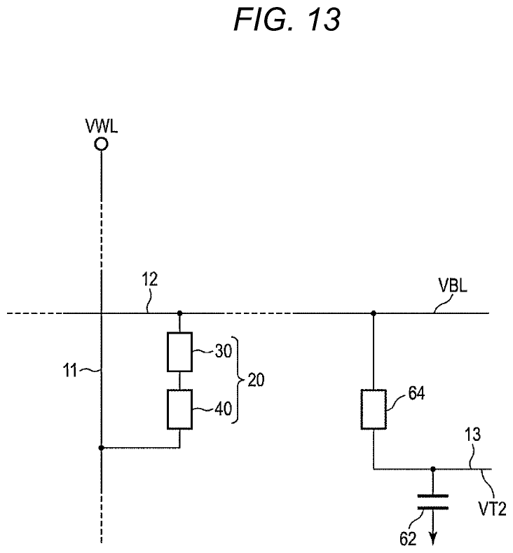

FIG. 12 is an electric circuit diagram showing a configuration of a circuit including a switching element of the storage device according to the present embodiment and the like. In the present embodiment, a MOS transistor 61B having a bipolarity is used as a switching element. It is possible to use a MOS transistor using germanium, a MOS transistor using graphene, a Schottky-type MOS transistor, or the like for the MOS transistor 61B. The other basic configurations are similar to those of the first and the second embodiments.

A basic read operation of the present embodiment is also similar to the read operations of the first and the second embodiments, and the time points t1, t2, t3L, and t3H are also similar to the time points t1, t2, t3L, and t3H of the first and the second embodiments.

The present embodiment is also similar to the first and the second embodiments: in basic configurations and basic operations and can obtain similar effects to those of the first and the second embodiments.

In addition, in the present embodiment, a switching element having a bipolarity is used. Therefore, the direction in which the current flows in the memory cell 20 does not need to be limited to one direction, and it is possible to obtain effects that the degree of freedom increases.

### Fourth Embodiment

Next, a storage device according to a fourth embodiment will be described. Basic matters are similar to those of the first and the second embodiments, and description of the matters described in the first and the second embodiments is omitted.

FIG. 13 is an electric circuit diagram showing a configuration of a circuit including a switching element of the storage device according to the present embodiment and the like.

In the present embodiment, as a switching element, a 2-terminal switching element 64 including the first terminal and the second terminal is used. The 2-terminal switching element 64 has a characteristic of shifting from off-state to on-state when the voltage higher than the threshold voltage is applied between the first terminal and the second terminal. The other basic configurations are similar to those of the first and the second embodiments.

A basic read operation of the present embodiment is also similar to the read operations of the first and the second embodiments, and the time points t1, t2, t3L, and t3H are also similar to the time points t1, t2, t3L, and t3H of the first and the second embodiments.

However, in the present embodiment, the voltage signal VBL from the bit line 12 is input to the first terminal of the 2-terminal switching element 64, and the voltage signal VT2 is output to the output wiring 13 from the second terminal of the 2-terminal switching element 64.

When the voltage signal VBL of the bit line 12 decreases and the voltage applied between the first terminal and the second terminal of the 2-terminal switching element 64 is lower than the threshold voltage, the 2-terminal switching element 64 shifts from on-state to off-state. That is, at the time point corresponding to the time point t3L or the time point t3H of the first embodiment, the 2-terminal switching element 64 shifts from on-state to off-state. As a result, a determination operation is performed after the time point t3L and the time point t3H, so that the determination operation similar to that of the first embodiment can be performed.

The present embodiment is also similar to the first and the second embodiments in basic configurations and basic operations and can obtain similar effects to those of the first and the second embodiments.

In addition, in the present embodiment, use of the 2-terminal switching element 64 as a switching element enables an entire configuration to be simplified.

An element having the configuration similar to that of the selector 40 provided in the memory cell 20 may be used for the 2-terminal switching element 64. In this case, the threshold voltage of the 2-terminal switching element 64 is desirably higher than the threshold voltage of the selector 40 so that the 2-terminal switching element 64 enters off-state before the selector 40 enters off-state. Use of an element having the configuration similar to that of the selector 40 for the 2-terminal switching element 64 enables an entire configuration to be simplified.

In the first to the fourth embodiments described above, the magnetoresistive effect element is used as a resistance change storage element; alternatively, other resistance change storage elements may be used.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A storage device comprising:
a first wiring extending in a first direction;
a second wiring extending in a second direction intersecting the first direction;
a memory cell provided between the first wiring and the second wiring, the memory cell including a resistance change storage element configured in a first resistance state or a second resistance state, and a selector connected in series to the resistance change storage element and configured to shift from off-state to on-state when voltage higher than a first threshold voltage is applied, the memory cell configured to store data based on a resistance state of the resistance change storage element;
a switching element configured to input a first signal from the second wiring and output a second signal to a third wiring different from the first wiring and the second wiring;
a voltage application circuit configured to apply a first voltage to the first wiring at a first time point such that a voltage higher than the first threshold voltage is applied to the selector; and
a determination circuit configured to determine the resistance state of the resistance change storage element based on the second signal output to the third wiring at a second time point after the first time point.

2. The storage device according to claim 1, wherein
a potential of the first signal decreases or increases after the first time point,
the determination circuit is configured to determine the resistance state of the resistance change storage element based on a potential at the second time point of the second signal depending on the potential of the first signal.

3. The storage device according to claim 2, wherein
the determination circuit is configured to determine the resistance state of the resistance change storage element by comparing the potential of the second signal at the second time point with a reference potential.

4. The storage device according to claim 2, wherein
a change in the potential of the first signal after the first time point allows the switching element to shift from the on-state to the off-state at a third time point.

5. The storage device according to claim 4, wherein
the second time point occurs after the third time point.

6. The storage device according to claim 4, wherein
the third time point is different from a case where a low resistance state is set in the resistance change storage element and a case where a high resistance state is set in the resistance change storage element.

7. The storage device according to claim 1, further comprising:
a capacitor coupled to the third wiring.

8. The storage device according to claim 1, wherein
the switching element is a metal oxide semiconductor (MOS) transistor including a gate terminal, a first terminal corresponding to one terminal of a source terminal and a drain terminal, a second terminal corresponding to the other terminal of a source terminal and a drain terminal, and
the first signal is input to the gate terminal and the second signal is output from the second terminal.

9. The storage device according to claim 8, wherein
the voltage application circuit is configured to change voltage of the first terminal at a time point before the second time point.

10. The storage device according to claim 9, wherein
a time point when the voltage application circuit changes the voltage of the first terminal is synchronized with the first time point.

11. The storage device according to claim 8, wherein
the MOS transistor has a bipolarity.

12. The storage device according to claim 1, wherein
the switching element includes a first terminal and a 2-terminal second terminal, and is a switching element configured to shift from the off-state to the on-state when a voltage applied between the first terminal and the second terminal is higher than second threshold voltage, and
the first signal is input to the first terminal, and the second signal is output from the second terminal.

13. The storage device according to claim 12, wherein
the second threshold voltage is higher than the first threshold voltage.

14. The storage device according to claim 1, wherein
the resistance change storage element and the selector are stacked in a third direction intersecting the first direction and the second direction.

15. The storage device according to claim 1, wherein
the resistance change storage element is a magnetoresistive effect element.
